(19) United States
(12) Patent Application Publication
(10) Pub. No.: US 2013/0328617 A1
(43) Pub. Date: Dec. 12, 2013

(54) TOUCH DEVICE AND METHOD FOR DETECTING TOUCH THEREOF

(71) Applicants: Jui-Ming Liu, Tainan City (TW); Li-Lin Liu, Tainan City (TW); Chung-Wen Chang, Tainan City (TW); Shen-Feng Tai, Tainan City (TW)

(72) Inventors: Jui-Ming Liu, Tainan City (TW); Li-Lin Liu, Tainan City (TW); Chung-Wen Chang, Tainan City (TW); Shen-Feng Tai, Tainan City (TW)

(73) Assignee: HIMAX TECHNOLOGIES LIMITED, Tainan City (TW)

(21) Appl. No.: 13/493,577

(22) Filed: Jun. 11, 2012

(51) Int. Cl. H03K 17/96

(52) U.S. Cl. 327/517

(57) ABSTRACT

A touch device and a method for detecting touch on the touch device are provided. The method includes the following steps. A plurality of touch values corresponding to a plurality touch region of a touch panel are obtained. A touch block is determined according the touch values and a touch threshold value, which the touch regions within the touch block are adjacent to one another. The touch values of the adjacent touch regions within the touch block are compared with one another to determine whether there is a touch value trough point in the touch block. It is determined that whether the touch block corresponds to a single touch or a multi-touch according to whether there is the touch value trough point in the touch block.

### BACKGROUND OF THE INVENTION

1. Field of Invention

The present invention relates to a touch device and a method for detecting touches using the touch device. More particularly, the present invention relates to a touch device capable of determining whether a touch block is corresponding to a single touch or a multi-touch and a method for detecting touches using the touch device.

2. Description of Related Art

With rapid developments and applications of the information technology, wireless mobile telecommunication, and information appliances, the input devices of many information products are changed from traditional keyboard, mouse and so forth to touch panels, so as to satisfy the requirements of convenience in carrying, light weight, and user-friendly operations. Currently, touch panels can be generally categorized into capacitive touch panels and resistive touch panels. With the increasing of the demands on the multi-touch technology, the projected capacitive touch technology becomes one of the main streams of touch panel technologies.

Since the human body can be regarded as a good conductor, the transparent electrode (such as indium-tin oxide electrode, ITO electrode) of the projected capacitive touch panel and the human body together form a capacitor. While the human body, such as the finger, approaches the projected capacitive touch panel, the capacitance of each of the touch regions of the projected capacitive touch panel varies. Accordingly, the touch point on which the human body touches the projected capacitive panel can be detected. However, two touch points are too closed to each other, which leads to that the touch regions with varied capacitances are adjacent to each other. Thus, the touch regions with varied capacitances are together regarded as a single touch point. Therefore, the touch device cannot correctly responses to the touch points where the user touches the touch panel.

### SUMMARY OF THE INVENTION

The invention is directed to a touch device and a method for detecting touches using the touch device capable of detecting whether a touch block is corresponding to a single touch or a multi-touch.

The present invention provides a touch device comprising a touch panel and a touch sensing unit. The touch panel comprises a plurality of touch regions. The touch sensing unit is coupled to the touch panel to detect a plurality of touch values corresponding to the touch regions and to determine a touch block according to the touch values and a touch threshold value. The touch sensing unit sequentially compares the touch values corresponding to the adjacent touch regions within the touch block with one another to determine whether there is a touch value trough point and determines whether the touch block corresponds to a single touch or a multi-touch based on whether there is the touch value trough point. The touch regions in the touch block are adjacent to one another.

According to one embodiment of the present invention, the touch sensing unit regards the touch region corresponding to a first maximum touch value as a first touch point and uses the first touch point as a comparison starting point to sequentially compare the touch values corresponding to the adjacent touch regions with one another. When a first touch value corresponding to one of the adjacent touch regions which is relatively farther away from the first touch point is larger than a second touch value corresponding to another of the adjacent touch regions which is relatively closer to the first touch point, the touch sensing unit determines the second touch value is the touch value trough point and determines the touch values corresponding to the first touch point according to the touch value trough point. The touch sensing unit regards the touch region which corresponds to a second maximum touch value among the touch values not corresponding to the first touch point as a second touch point.

According to one embodiment of the present invention, when the touch values corresponding to the touch block have been compared with one another already, the touch sensing unit stops determining the touch value trough point of the touch block.

According to one embodiment of the present invention, when there is no touch value trough point, the touch sensing unit determines the touch block corresponds to the single touch. When the there is a touch value through point, the touch sensing unit determines the touch block corresponds to the multi-touch.

According to one embodiment of the present invention, the touch panel includes a projected capacitive touch panel or a digital resistive touch panel.

The present invention further provides a method for detecting touch on a touch device and comprises steps of obtaining a plurality of touch values respectively corresponding to a plurality of touch regions of a touch panel and, according to the touch values and a touch threshold value, determining a touch block, wherein the touch regions within the touch block are adjacent to one another. The touch values corresponding to the adjacent touch regions within the touch block are sequentially compared with one another to determine whether there is a touch value trough point. According to whether there is a touch value trough point, it is determined whether the touch block corresponds to a single touch or a multi-touch.

According to one embodiment of the present invention, the step of sequentially comparing the touch values corresponding to the adjacent touch regions within the touch block with each other to determine whether there is the touch value trough point comprises regarding the touch region with a first maximum touch value among the touch values corresponding to the touch block as a first touch point. The touch values corresponding to the adjacent touch regions are sequentially compared with one another by using the first touch point as a comparison starting point. When a first touch value corresponding to one of the adjacent touch regions which is relatively farther away from the first touch point is larger than a second touch value corresponding to another of the adjacent touch regions which is relatively closer to the first touch point, the second touch value is determined to be the touch value trough point. The touch values corresponding to the first touch point is determined according to the touch value trough point and the touch region which corresponds to a second maximum touch value among the touch values not corresponding to the first touch point is regarded as a second touch point.

According to one embodiment of the present invention, the step of detecting the touch on the touch panel further comprises, when the touch values corresponding to the touch block have been compared with one another already, stopping determining the touch value trough point of the touch block.

According to one embodiment of the present invention, each of the touch values corresponding to the touch block is larger than or equal to the touch threshold value.

According to one embodiment of the present invention, the step of determining whether the touch block corresponds to the single touch or the multi-touch according to whether there is a touch value trough point comprises when there is no touch value trough point, determining the touch block corresponds to the single touch and when the there is a touch value through point, determining the touch block corresponds to the multi-touch.

Accordingly, in the touch device and the method for detecting touches used by the touch device of the embodiments of the present invention, the touch values corresponding to the adjacent touch regions within the touch block are sequentially compared to one another to determine whether there is a touch value trough point and it is determined that whether the touch block corresponds to the single touch or the multi-touch based on whether there is the touch value trough point. Further, according to the determined touch value trough point, the touch points respectively corresponding to the touch regions within the touch block are differentiated.

It is to be understood that both the foregoing general description and the following detailed description are exemplary, and are intended to, provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic diagram showing a touch device according to one embodiment of the invention.

FIG. 2 is a touch value distribution diagram of the touch panel shown in FIG. 1.

FIG. 3 is a flow chart showing a method for detecting touches using a touch device according to one embodiment of the present invention.

### DESCRIPTION OF THE PREFERRED EMBODIMENTS

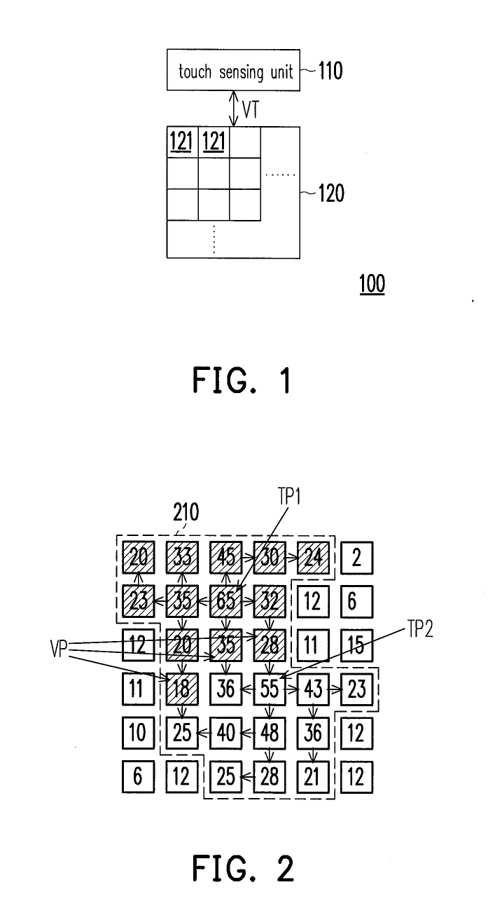

FIG. 1 is a schematic diagram showing a touch device according to one embodiment of the invention. As shown in FIG. 1, a touch device 100 comprises a touch sensing unit 110 and a touch panel 120. The touch panel 120 comprises several touch regions 121 and the touch panel 120 can be, for example, a projected capacitive touch panel or digital resistive touch panel. The touch sensing unit 110 is coupled to the touch panel 120 for detecting a plurality of touch values VT corresponding to the touch regions 121, determining whether the touch panel 120 is touched and the touch point on the touch panel 120 according to the detected touch values VT.

More specifically, after obtaining the touch values VT corresponding to the touch regions 121, the touch sensing unit 110 determines whether there are touch blocks within the touch panel 120 according to the touch values of the touch regions 121 and the touch threshold value. The touch sensing unit 110 filters out the touch regions with which the corresponding touch value VT is smaller than the touch threshold value. Further, when there are touch regions which are not filtered out, the touch regions among these touch regions that not filter out which are adjacent to one another are together regarded as a touch block. In other words, the touch values VT corresponding to the touch regions belonging to the touch block are larger than or equal to the touch threshold value and the touch regions belonging to the same touch block are adjacent to one another. When all of the touch regions are filtered out, there is no touch block.

When the touch sensing unit 110 determines there is no touch block within the touch panel 120, it represents that the touch panel has not been touched. In other words, there is no touch point on the touch panel 120. Meanwhile, the touch sensing unit 110 stops further detection action or procedures. When the touch sensing unit 110 detects one touch block, it means the touch panel 120 is at a status that the touch panel 120 is touched. In other words, there are at least one touch point on the touch panel 120. Meanwhile, the touch sensing unit 110 performs a data processing procedure on the touch value VT corresponding to the same touch block to determine whether the touch block is corresponding to the single touch or the multi-touch and to determine the touch point of the touch block.

During the data processing procedure, the touch sensing unit 110 regards the touch region corresponding to the maximum touch value (i.e. the first maximum touch value) as a first touch point and sequentially compares the touch values corresponding to the adjacent touch regions with one another by using the first touch point as the comparison starting point. When, among two adjacent touch regions, the touch value VT (i.e. the first touch value) of one touch region which is relatively farther away from the first touch point is larger than the touch value VT (i.e. the second touch value) of the other touch region which is relatively closer to the first touch point, the touch sensing unit 110 determines the touch value VT of the touch region which is relatively closer to the first touch point to be a touch value trough point. Moreover, the touch sensing unit 110 determines whether the touch value corresponding to the touch region corresponds to the first touch point according to the determined touch value trough point. That is, according to the determined touch value trough point, the touch block is divided, wherein the touch values of the touch regions including the first touch point correspond to the first touch point and the touch values of the touch regions which do not include the first touch point do not correspond to the first touch point.

In addition, the touch region having the maximum touch value (i.e. the second maximum touch value) among the touch values VT which are not corresponding to the first touch point is regarded as a second touch point and it is determined whether there are other touch value trough points in order to determine whether there are other touch points according to the aforementioned determination procedure. After all of the touch values corresponding to the touch block are compared with one another, the data processing procedure of the touch regions is finished. Therefore, the touch sensing unit 110 stops detecting the touch value trough point of the touch block. Accordingly, the touch sensing unit 110 determines whether the touch block corresponds to the single touch or the multi-touch based on whether the touch value trough point is determined and further differentiates the touch points corresponding to the touch regions within the touch block from one another based on the determined touch value trough point.

FIG. 2 is a touch value distribution diagram of the touch panel shown in FIG. 1. As shown in FIG. 1 and FIG. 2, in the present embodiment, the touch regions 121 of the touch panel 120 are arranged in a 6-by-6 array and the detected touch values VT are shown as the numbers in the lattices in FIG. 2. Herein, assuming the touch threshold value is 20, the touch regions with the touch values VT smaller than 20 are filtered out (that is, the touch regions with the touch values VT smaller than 20 are not selected) and the touch block 210 is determined according to the selected touch regions which are adjacent to one another.

After determining the touch block 210, the touch sensing unit 110 defines the touch region with the maximum touch value (which is 65 herein) as the first touch point TP1. Then, starting from the first touch point TP1, the touch values of two adjacent touch regions in the touch block 210 are compared with each other, wherein the comparison path can be referred to the arrow shown in FIG. 2. In the present embodiment, the touch sensing unit 110 compares the touch value which is 65 with the touch values (which are 32, 35 and 45) corresponding to the touch regions adjacent to the first touch point TP1 ahead. Since the touch value (which is 65) of the first touch point is larger than the touch values (which are 32, 35 and 45) respectively corresponding to the touch regions adjacent to the first touch point TP1, the touch value of the first touch point is not regarded as the touch value trough point VP.

As shown in FIG. 2, the touch value of 32 corresponding to the touch region which is adjacent to the right-hand side of the first touch point TP1 is compared with the touch value of 28 corresponding to the touch region which is adjacent to the bottom side of the former touch region with the touch value of 32. Further, the aforementioned touch value of 28 is compared with the touch value of 55 corresponding to the touch region adjacent to the bottom side of the former touch region with the touch value of 28. According to the comparison result, the touch value of 32 is not regarded as the touch value trough point VP and the touch value of 28 is regarded as the touch value trough point VP. The touch value of 35 corresponding to the touch region adjacent to the bottom side of the first touch point TP1 is compared with the touch value of 36 corresponding to the touch region adjacent to the bottom side of the former touch region with the touch value of 35 and, according to the comparison result, the touch value of 35 is regarded as the touch value trough point VP. Further, the touch value of 35 corresponding to the touch region adjacent to the left-hand side of the first touch point TP1 is compared with the touch values of 20, 23 and 33 corresponding to the touch regions respectively adjacent to the bottom side, the left-hand side and the top side of the former touch regions with the touch value of 35. Moreover, the aforementioned touch value of 20 is compared with the touch value of 18 corresponding to the touch region adjacent to the bottom side of the former touch region with the touch value of 20, the aforementioned touch value of 18 is compared with the touch value of 25 corresponding to the touch region adjacent to the bottom side of the touch region with the touch value of 18 and the aforementioned touch value of 23 is compared with the touch value of 20 corresponding to the touch region adjacent to the top side of the touch region with the touch value of 23. Therefore, according to the comparison result, the touch values of 35, 33, 20 and 23 are not regarded as the touch value trough point VP and the touch value of 18 is determined to be the touch value trough point VP. The touch value of 45 corresponding to the touch region adjacent to the top side of the first touch point TP1 is compared with the touch value of 30 corresponding to the touch region adjacent to the right-hand side of the former touch region with touch value of 45 and the aforementioned touch value of 30 is compared with the touch value of 24 corresponding to the touch region adjacent to the right-hand side of the touch region with the touch value of 30. According to the comparison result, the touch values of 45, 30 and 24 are not regarded as the touch value trough point VP.

Accordingly, when the touch value (such as 28, 35 and 18) are determined as the touch value trough points VP, theses touch value trough points VP are not further compared with other touch value in the touch value comparison. Furthermore, by using these touch value trough points VP, the touch block 210 are divided into two areas (such as the oblique-line filled lattice area and the blank lattice area shown in FIG. 2), wherein all of the touch values (as the numbers shown in the oblique-line filled lattices) corresponding to the touch regions in the area including the first touch point TP1 correspond to the first touch point TP1. Then, among the touch regions within the area not including the first touch point TP1 (i.e. having the touch values not corresponding to the first touch point TP1), the touch region corresponding to the maximum touch value (which is 55 herein) is determined to be the second touch point TP2. Thereafter, except for being compared with the touch value trough point VP which is 28, the touch value of 55 corresponding to the second touch point TP2 is compared with the touch values (which are 43, 48 and 36) respectively corresponding to the touch regions adjacent to the second touch point TP2. Since the touch value of 55 is larger than the touch values of 43, 48 and 38 respectively, the touch value of 55 is not determined to be the touch value trough point VP.

According to FIG. 2, the touch value of 43 corresponding to the touch region adjacent to the right-hand side of the second touch point TP2 is compared with the touch values of 23 and 36 respectively corresponding to the touch regions respectively adjacent to the right-hand side and the bottom side of the touch region with the touch value of 43 and the aforementioned touch value of 36 is compared with the touch value of 21 corresponding to the touch region adjacent to the bottom side of the touch region corresponding to the touch value of 36. According to the comparison result, the touch values of 43, 23 and 36 are not regarded as the touch value trough point VP. The touch value of 48 corresponding to the touch region adjacent to the bottom side of the second touch point TP2 is compared with the touch values of 40 and 28 respectively corresponding to the touch regions respectively adjacent to the left-hand side and the bottom side of the touch region with the touch value of 48. Further, the aforementioned touch value of 28 is compared with the touch value of 25 corresponding to the touch region adjacent to the left-hand side of the touch region with the touch value of 28 and the aforementioned touch value of 40 is compared with the touch value of 25 corresponding to the touch region adjacent to the left-hand side of the touch region with the touch value of 40. According to the comparison result, the touch values of 48, 28, 40 and 25 are not regarded as the touch value trough point VP. Moreover, the touch values which are corresponding to the touch regions adjacent to the touch region adjacent to the left-hand side of the second touch point TP2 and have been determined to be the touch value trough points VP, the touch value corresponding to the second touch point TP2 or other touch values which are already used in the touch value comparison are not used to compare with the touch value of 36 so that the touch value of 36 is not regarded as the touch value trough point VP.

Accordingly, the touch sensing unit 110 determines the touch block 210 corresponds to the multi-touch and determines the touch value trough point VP by comparing the touch values corresponding to two adjacent touch regions. Further, by using the touch value trough point VP, the touch sensing unit 110 determines the touch points (such as the first touch point TP1 or the second touch point TP2) respectively corresponding to the touch regions (i.e. touch values). Therefore, when the plurality of the touch point are too close to one another which leads to the touch regions corresponding to the touch points are adjacent to one another, the touch sensing unit 110 divides the touch regions respectively corresponding to the touch points by referring to the touch value trough point VP. Hence, the aforementioned adjacent touch regions are not erroneously determined to be corresponding to the same touch point.

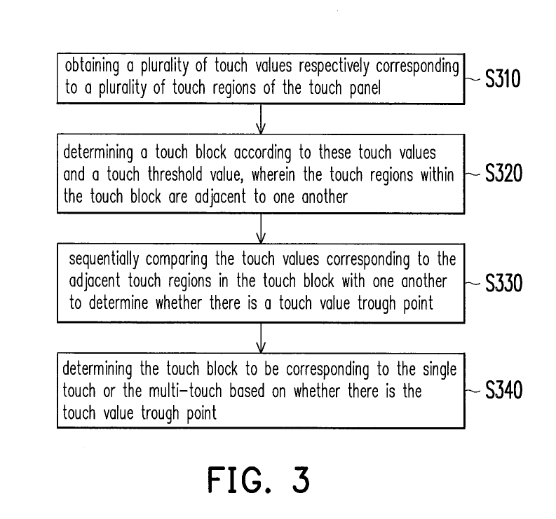

FIG. 3 is a flow chart showing a method for detecting touches using a touch device according to one embodiment of the present invention. As shown in FIG. 3, in the present embodiment, the method for detecting the touches used in the touch device comprises the following steps. A plurality of touch values respectively corresponding to a plurality of touch regions of the touch panel are obtained (step S310). According to these touch values and a touch threshold value, a touch block is determined, wherein the touch regions within the touch block are adjacent to one another (step S320). The touch values corresponding to the adjacent touch regions in the touch block are sequentially compared with one another to determine whether there is a touch value trough point (step S330). The touch block is determined to be corresponding to the single touch or the multi-touch based on whether there is the touch value trough point (step S340). Moreover, when all of the touch values corresponding to the touch regions within the touch block have been used in the touch value comparison, the determination of the touch value trough point from the touch values corresponding to the touch regions within the touch block is stopped. The details of the aforementioned steps can be referred to the descriptions of FIG. 1 and FIG. 2 and are not repeatedly described herein.

Altogether, in the touch device and the method for detecting touches used by the touch device of the embodiments of the present invention, the touch values corresponding to the adjacent touch regions within the touch block are sequentially compared to one another to determine whether there is a touch value trough point and it is determined that whether the touch block corresponds to the single touch or the multi-touch based on whether there is the touch value trough point. Further, according to the determined touch value trough point, the touch points respectively corresponding to the touch regions within the touch block are differentiated.

It will be apparent to those skilled in the art that various modifications and variations can be made to the structure of the present invention without departing from the scope or spirit of the invention. In view of the foregoing descriptions, it is intended that the present invention covers modifications and variations of this invention if they fall within the scope of the following claims and their equivalents.

What is claimed is:

1. A touch device, comprising:
a touch panel having a plurality of touch regions; and
a touch sensing unit coupling to the touch panel to detect a plurality of touch values corresponding to the touch regions and to determine a touch block according to the touch values and a touch threshold value, wherein the touch sensing unit sequentially compares the touch values corresponding to the adjacent touch regions within the touch block with one another to determine whether there is a touch value trough point and determines whether the touch block corresponds to a single touch or a multi-touch based on whether there is the touch value trough point and the touch regions in the touch block are adjacent to one another.

2. The touch device of claim 1, wherein the touch sensing unit regards the touch region corresponding to a first maximum touch value as a first touch point, uses the first touch point as a comparison starting point to sequentially compare the touch values corresponding to the adjacent touch regions with one another and when a first touch value corresponding to one of the adjacent touch regions which is relatively farther away from the first touch point is larger than a second touch value corresponding to another of the adjacent touch regions which is relatively closer to the first touch point, the touch sensing unit determines the second touch value is the touch value trough point and determines the touch values corresponding to the first touch point according to the touch value trough point and regards the touch region which corresponds to a second maximum touch value among the touch values not corresponding to the first touch point as a second touch point.

3. The touch device of claim 1, wherein when the touch values corresponding to the touch block have been compared with one another already, the touch sensing unit stops determining the touch value trough point of the touch block.

4. The touch device of claim 1, wherein each of the touch values corresponding to the touch block is larger than or equal to the touch threshold value.

5. The touch device of claim 1, wherein when there is no touch value trough point, the touch sensing unit determines the touch block corresponds to the single touch, and when the there is a touch value through point, the touch sensing unit determines the touch block corresponds to the multi-touch.

6. The touch device of claim 1, wherein the touch panel is a projected capacitive touch panel or a digital resistance touch panel.

7. A method for detecting touch on a touch device, comprising:
obtaining a plurality of touch values respectively corresponding to a plurality of touch regions of a touch panel;
according to the touch values and a touch threshold value, determining a touch block, wherein the touch regions within the touch block are adjacent to one another;
sequentially comparing the touch values corresponding to the adjacent touch regions within the touch block with each other to determine whether there is a touch value trough point; and
according to whether there is a touch value trough point, determining whether the touch block corresponds to a single touch or a multi-touch.

8. The method of claim 7, wherein the step of sequentially comparing the touch values corresponding to the adjacent touch regions within the touch block with one another to determine whether there is the touch value trough point comprises:
regarding the touch region with a first maximum touch value among the touch values corresponding to the touch block as a first touch point;
sequentially comparing the touch values corresponding to the adjacent touch regions with one another by using the first touch point as a comparison starting point;
when a first touch value corresponding to one of the adjacent touch regions which is relatively farther away from the first touch point is larger than a second touch value corresponding to another of the adjacent touch regions which is relatively closer to the first touch point, determining the second touch value to be the touch value trough point; and
determining the touch values corresponding to the first touch point according to the touch value trough point and regarding the touch region which corresponds to a second maximum touch value among the touch values not corresponding to the first touch point as a second touch point.

9. The method of claim 7, further comprising:
when the touch values corresponding to the touch block have been compared with one another already, stopping determining the touch value trough point of the touch block.

10. The method of claim 7, wherein each of the touch values corresponding to the touch block is larger than or equal to the touch threshold value.

11. The method of claim 7, wherein the step of determining whether the touch block corresponds to the single touch or the multi-touch according to whether there is a touch value trough point comprises:
when there is no touch value trough point, determining the touch block corresponds to the single touch; and
when the there is a touch value through point, determining the touch block corresponds to the multi-touch.
